(19) United States
(12) Patent Application Publication
(10) Pub. No.: US 2018/0190763 A1
(43) Pub. Date: Jul. 5, 2018

(54) HIGH-VOLTAGE SEMICONDUCTOR DEVICE

(71) Applicant: Nuvoton Technology Corporation, Hsinchu (TW)

(72) Inventors: Shao-Ming YANG, Taipei City (TW); Ting-Yao CHIEN, New Taipei City (TW); Chieh-Chih WU, Keelung City (TW); Tzu-Chieh LEE, Taipei City (TW); Chiu-Chung LAI, Taipei City (TW)

(21) Appl. No.: 15/859,050

(22) Filed: Dec. 29, 2017

(30) Foreign Application Priority Data
Dec. 30, 2016 (TW) 105144151

(51) Int. Cl. H01L 29/06; H01L 29/08; H01L 29/78

(52) U.S. Cl. CPC H01L 29/0623; H01L 29/0878; H01L 29/66681; H01L 29/7835; H01L 29/7816

(57) ABSTRACT

High-voltage semiconductor devices are provided. The high-voltage semiconductor device includes a substrate having a first conductive type and a gate region disposed on the substrate. The high-voltage semiconductor also includes a source region and a drain region disposed on two sides of the gate region respectively. The high-voltage semiconductor also includes a linear doped region disposed between the gate region and the drain region, wherein the linear doped region has a nonuniform doping depth and the first conductive type. The high-voltage semiconductor further includes a first buried layer disposed under the source region and having the first conductive type.

### CROSS REFERENCE TO RELATED APPLICATIONS

This Application claims priority of Taiwan Patent Application No. 105144151, filed on Dec. 30, 2016, entitled “high-voltage semiconductor device”, which is hereby incorporated by reference in its entirety.

### BACKGROUND OF THE INVENTION

### Field of the Invention

The present invention relates to a semiconductor device and in particular to a high-voltage semiconductor device.

### Description of the Related Art

High-voltage semiconductor devices are applied to integrated circuits with high-voltage and high power. Traditional high-voltage semiconductor devices, such as a vertically diffused metal oxide semiconductor (VDMOS) transistor or a laterally diffused metal oxide semiconductor (LDMOS) transistor, are mainly used for devices with at least 18 volts or higher in the application field. The advantages of high-voltage device technology include cost effectiveness and process compatibility. High-voltage device technology has been widely used in display driver IC devices, power supply devices, and such fields as power management, communications, automatics, and industrial control.

During the development of high-voltage semiconductor devices, it is a difficult goal to have a high-voltage semiconductor device with both high breakdown voltage and low on-resistance (Ron). Therefore, it is necessary to search for a new high-voltage semiconductor device that can meet the requirements described above.

### BRIEF SUMMARY OF THE INVENTION

Some embodiments of the present disclosure relate to a high-voltage semiconductor device. The high-voltage semiconductor device includes a substrate having a first conductive type, a gate disposed on the substrate, a source region and a drain region disposed on two opposite sides of the gate, respectively, a linear doped region disposed between the gate and the drain region and having the first conductive type, wherein the linear doped region has a nonuniform doping depth, and a first buried layer disposed under the source region and having the first conductive type.

Some embodiments of the present disclosure relate to a high-voltage semiconductor device. The high-voltage semiconductor device includes a gate extending in a first direction, a source region and a drain region disposed on two opposite sides of the gate respectively, and extending in the first direction, an isolation region disposed between the gate and the drain region and having a plurality of separate isolation blocks, and a linear doped region disposed between the gate and the drain region, and between the plurality of isolation blocks, wherein the linear doped region has a nonuniform doping depth in a second direction perpendicular to the first direction.

### BRIEF DESCRIPTION OF THE DRAWINGS

The present invention can be more fully understood by reading the subsequent detailed description and examples with references made to the accompanying drawings, wherein:

FIG. 1 is a top view of a high-voltage semiconductor device in accordance with some embodiments of the present invention.

FIG. 2 is a cross-sectional view taken along a line A-A′ of the high-voltage semiconductor device of FIG. 1 in accordance with some embodiments.

FIG. 3 is a cross-sectional view taken along a line B-B′ of the high-voltage semiconductor device of FIG. 1 in accordance with some embodiments.

FIG. 4 is a cross-sectional view taken alone a line B-B′ of the high-voltage semiconductor device of FIG. 1 in accordance with other embodiments.

### DETAILED DESCRIPTION OF THE INVENTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

The terms “about” and “substantially” typically mean+/−20% of the stated value, more typically +/−10% of the stated value, more typically +/−5% of the stated value. The stated value of the present disclosure is an approximate value. When there is no specific description, the stated value includes the meaning of “about” or “substantially”.

It should also be noted that the present disclosure presents embodiments of a high-voltage semiconductor device, and may be included in an integrated circuit (IC) such as a microprocessor, memory device, and/or another IC. The IC may also include various passive and active microelectronic devices, such as thin film resistors, other capacitors (e.g. metal-insulator-metal capacitor, MIMCAP), inductors, diodes, metal-oxide-semiconductor field effect transistors (MOSFETs), complementary MOS (CMOS) transistors, bipolar junction transistors (BJTs), laterally diffused MOS (LDMOS) transistors, high power MOS transistors, or other types of transistors. One of ordinary skill may understand that high-voltage semiconductors can be used in integrated circuits including other types of semiconductor devices.

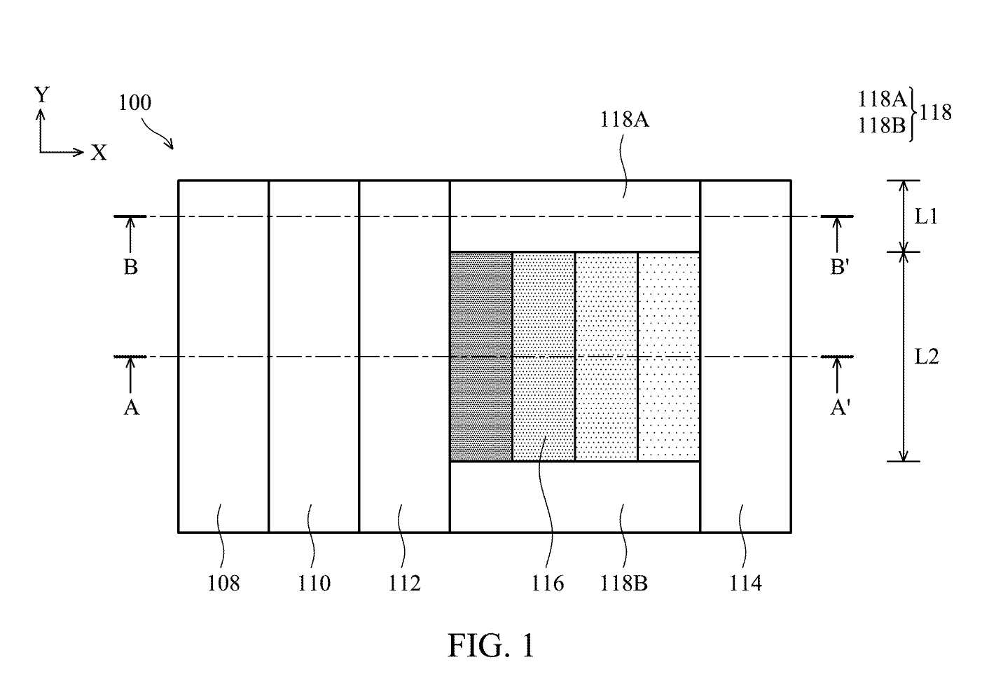

Referring to FIG. 1, FIG. 1 is a top view of a high-voltage semiconductor device 100 in accordance with some embodiments of the present invention. As shown in FIG. 1, the high-voltage semiconductor device 100 includes a first doped region 108, a second doped region 110, a gate 112 and a third doped region 114, respectively along a first direction such as Y direction, wherein the first doped region 108 and the second doped region 110 can be a source region of the high-voltage semiconductor device 100, and the third doped region 114 can be a drain region of the high-voltage semiconductor device 100. In addition, the first doped region 108, the second doped region 110 and the third doped region 114 can be heavily doped regions or lightly doped regions.

As shown in FIG. 1, in some embodiments, the high-voltage semiconductor device 100 further includes an isolation region 118 and a linear doped region 116. The isolation region 118 is disposed between the gate 112 and the drain region 114, and the isolation region 118 is separated into a plurality of blocks in the first direction, for example, an isolation block 118A and an isolation block 118B separated from each other. The linear doped region 116 is disposed between the isolation block 118A and the isolation block 118B. In the pattern of the linear doped region 116, the density of the dots represents doping depth and/or concentration, wherein the higher the density of the dots is, the deeper the doping depth is, or the higher the doping concentration is; and the lower the density of the dots is, the lighter the doping depth is, or the lower the doping concentration is. In some embodiments, along a second direction, such as the X direction, the depth and/or concentration of the linear doped region 116 is nonuniform. As shown in FIG. 1, in a direction from the gate 112 to the third doped region 114 (i.e. drain region), the doping depth and/or concentration of the linear doped region 116 tapers.

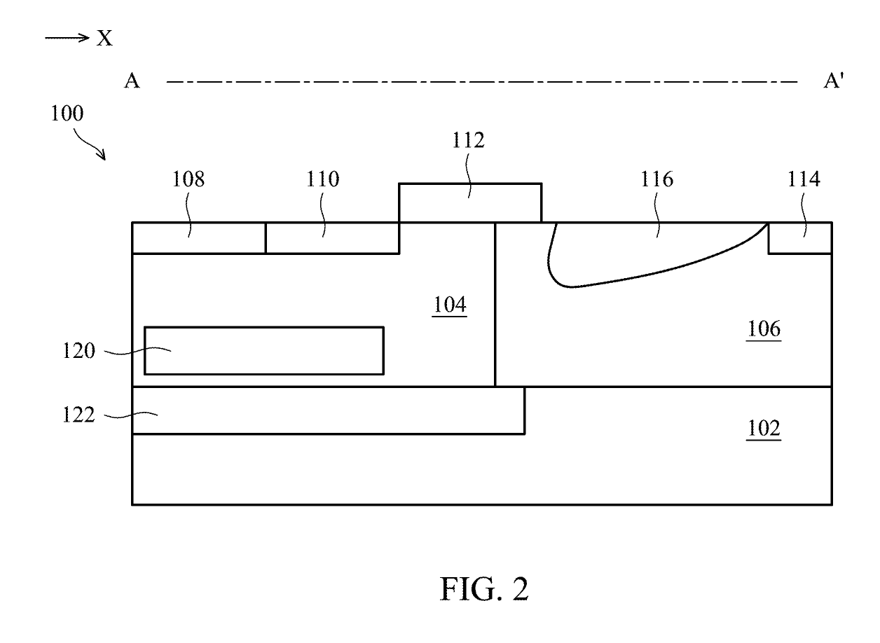

Referring to FIG. 2, FIG. 2 is a cross-sectional view taken along a line A-A′ of the high-voltage semiconductor device 100 of FIG. 1 in accordance with some embodiments. As shown in FIG. 2, the high-voltage semiconductor device 100 includes a substrate 102. The substrate 102 can be a semiconductor substrate such as a silicon substrate. The semiconductor substrate can also be an element semiconductor, including germanium, a compound semiconductor including silicon carbide, gallium arsenide, gallium phosphide, indium phosphide, indium arsenide and/or indium antimonide, an alloy semiconductor including SiGe, GaAsP, AlInAs, AlGaAs, GalnAs, GaInP and/or GaInAsP or a combination thereof. In addition, the substrate 102 can also be a semiconductor on insulator (SOI). In some embodiments, the substrate 102 has a first conductive type, such as P type.

As shown in FIG. 2, the high-voltage semiconductor device 100 includes a first well region 104 and a second well region 106, wherein the first well region 104 has the first conductive type and the second well region 106 has a second conductive type, for example, N type, different from the first conductive type, wherein the doping concentration of the first well region 104 can be such as 10¹⁴ cm³-10¹⁸ cm³, and the doping concentration of the second well region 106 can be such as 10¹⁴ cm³-10¹⁸ cm³.

In some embodiments, the second well region 106 can be replaced with an epitaxial layer doped with the second conductive type. The epitaxial layer may include Si, Ge, Si and Ge, Group V compound or a combination thereof. The epitaxial layer may be formed by epitaxial growth process, for example, metal-organic chemical vapor deposition (MOCVD), metal-organic vapor phase epitaxy (MOVPE), plasma-enhanced chemical vapor deposition (PECVD), remote plasma chemical vapor deposition (RP-CVD), molecular beam epitaxy (MBE), hydride vapor phase epitaxy (HVPE), liquid phase epitaxy (LPE), chloride vapor phase epitaxy (Cl-VPE) or the like.

As shown in FIG. 2, the gate 112 is disposed on the substrate 102. The gate 112 includes a gate dielectric layer and a gate electrode (not shown). The material of the gate dielectric layer may include silicon oxide, silicon nitride, silicon oxynitride, high-k dielectric material, or any other applicable dielectric material, or a combination thereof. The high-k dielectric material may be metal oxide, metal nitride, metal silicide, transition metal oxide, transition metal nitride, transition metal silicide, metal oxynitride, metal aluminate, zirconium silicate, or zirconium aluminate. For example, the high-k dielectric material may be LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfTiO, HfTaTiO, HfAlON, (Ba, Sr)TiO₃(BST), Al₂O₃, another applicable high-k dielectric material, or a combination thereof. The dielectric material layer may be formed by CVD or spin coating. The gate electrode includes amorphous silicon, polysilicon, one or more metals, metal nitride, conductive metal oxide, or a combination thereof. The metal may include, but is not limited to, molybdenum, tungsten, titanium, tantalum, platinum, or hafnium. The metal nitride may include, but is not limited to, molybdenum nitride, tungsten nitride, titanium nitride or tantalum nitride. The conductive metal oxide may include, but is not limited to, ruthenium oxide or indium tin oxide. The material of the conductive material layer may be formed by chemical vapor deposition (CVD), sputtering, resistive thermal evaporation, electron beam evaporation, or any other suitable method.

The source region consisting of the first doped region 108 and the second doped region 110 is disposed in the first well region 104, and the first doped region 108 and the second doped region 110 have the first conductive type and the second conductive type, respectively. The drain region consisting of the third doped region 114 is disposed in the second well region 106 and has the second conductive type.

In some embodiments, the high-voltage semiconductor device includes a linear doped region 116 disposed in the second well region 106, and between the gate 112 and the third doped region 114. In some embodiments, the linear doped region 116 has the first conductive type. As shown in FIG. 2, the doping depth of the linear doped region 116 is not uniform, and the doping depth of the linear doped region 116 tapers in a direction from the gate 112 to the third doped region 114. Although not shown in FIG. 2, in some other embodiments, the doping concentration of the linear doped region 116 is not uniform, and the doping concentration of the linear doped region 116 tapers in a direction from the gate 112 to the third doped region 114. In some embodiments, the doping concentration of the linear doped region 116 may be in a range around from 10¹⁵ cm³ to 10¹⁸ cm³.

In some embodiments, as shown in FIG. 2, the high-voltage semiconductor device 100 includes a first buried layer 120 disposed in the first well region 104, and under the first doped region 108 and the second doped region 110 (i.e. the source region). The first buried layer 120 has the first conductive type, and the doping concentration of the first buried layer 120 may be uniform or nonuniform. In some embodiments, the doping concentration of the first buried layer 120 tapers in a direction from the source region to the gate 112. The doping concentration of the first buried layer 120 may be in a range around from 10¹⁶ cm³ to 10¹⁹ cm³. Additionally, in some embodiments, the projection of the first buried layer 120 on the substrate 102 does not overlap that of the gate 112 on the substrate 102. Also, the first buried layer 120 is completely covered by the source region.

The high-voltage semiconductor device 100 includes a second buried layer 122 disposed in the substrate 102 and having the second conductive type. As shown in FIG. 2, the second buried layer 122 is disposed under the first buried layer 120. In some embodiments, the length of the first buried layer 120 projecting onto the substrate is smaller than that of the second buried layer 122. In addition, the second buried layer 122 extends from under the first well region 104 to under the second well region 106 and the gate 112. In some embodiments, a part of the projection of the gate 112 on the substrate 102 does not overlap the second buried layer 122, and the projection of the linear doped region 116 on the substrate 102 does not overlap the second buried layer 122. Additionally, although not shown in FIG. 2, in some other embodiments, the second buried layer 122 may be formed completely on the substrate 102. In the embodiments, the projection of the gate 112 on the substrate 102 completely overlaps the second buried layer 122, and the projection of the linear doping 116 on the substrate 102 completely overlaps the second buried layer 122. In some embodiments, the projection of the first buried layer 120 on the substrate 102 does not overlap that of the gate 112 on the substrate 102. In some embodiments, the doping concentration of the second buried layer 122 may be in a range around from 10¹⁶ cm³ to 10¹⁹ cm³.

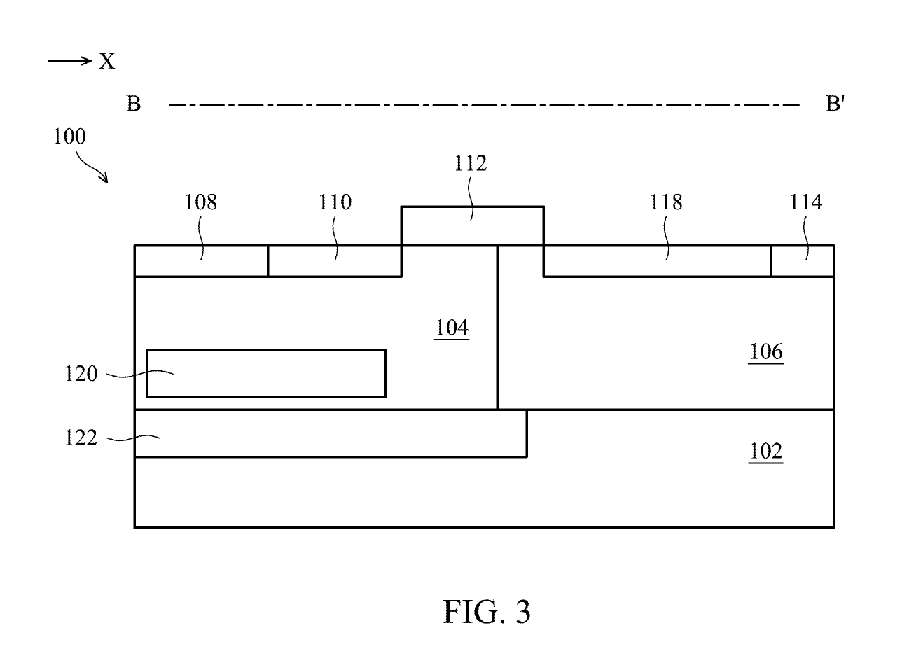

Referring to FIG. 3, FIG. 3 is a cross-sectional view taken along a line B-B′ of the high-voltage semiconductor device of FIG. 1 in accordance with some embodiments. As shown in FIG. 3, the high-voltage semiconductor device 100 includes the isolation region 118. In some embodiment, the isolation region 118 is a shallow trench isolation structure, and is formed of dielectric material, for example, silicon oxide, silicon nitride, silicon oxynitride or other dielectric materials. A photolithography and an etching process may be performed to form a trench (not shown) in the second well region 106, and subsequently fill the trench with the above dielectric materials. The photolithography process includes photoresist coating (e.g., spin-on coating), soft baking, mask alignment, exposure, post-exposure baking, developing the photoresist, drying (e.g., hard baking), other suitable processes or a combination thereof. The photolithography process may also be implemented or replaced by another proper method such as maskless photolithography, electron-beam writing or ion-beam writing. The etching process includes dry etching, wet etching or other etching methods.

In some embodiments, as shown in FIG. 3, in the second direction, the linear doped region 116 does not extend under the isolation region 118, i.e., the linear doped region 116 is only formed between the two isolation blocks 118A and 118B as shown in FIG. 1. Also, as shown in FIG. 3, in some embodiments, the second buried layer 122 does not extend under the isolation region 118.

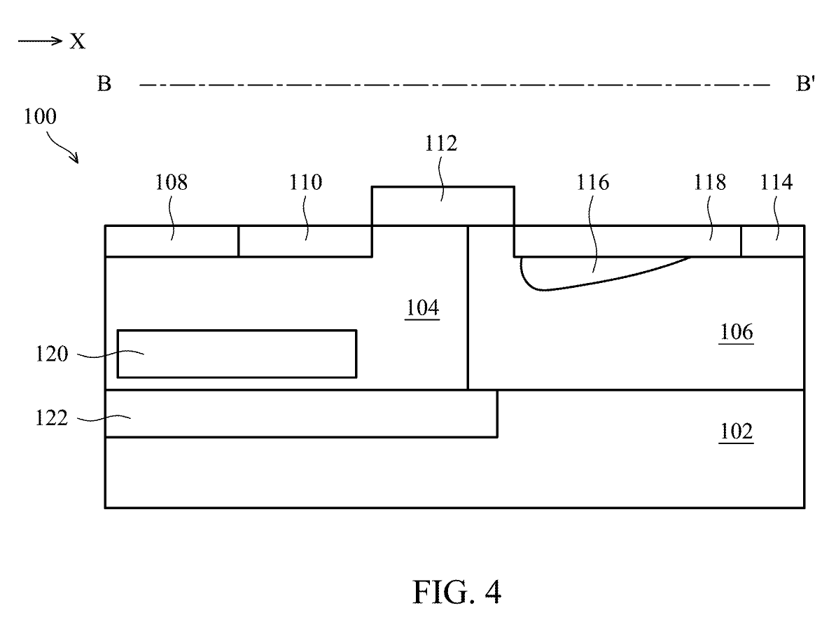

Referring to FIG. 4, FIG. 4 is a cross-sectional view taken along a line B-B′ of the high-voltage semiconductor device of FIG. 1 in accordance with some embodiments. The difference between the embodiments shown in FIG. 4 and FIG. 3 is that the linear doped region 116 is not only formed between the two isolation blocks 118A and 118B as shown in FIG. 1, but also formed under the isolation blocks 118A and 118B. That is, in the second direction, the linear doped region 106 extends under the isolation region 118.

Referring back to FIG. 1, as shown in FIG. 1, the isolation block 118A and the isolation block 118B have a length, L1 in the second direction, and the distance between the two isolation blocks 118A and 118B is a length, L2. In some embodiments, the ratio of L2 to L1 is from 1:1 to 10:1, preferably 4:1 to 6:1. In the embodiments as shown in FIG. 3, when the linear doped region 116 is only formed between the two isolation blocks 118A and 118B, the ratio of the length of the linear doped region 116 in the second direction to L1 is from 1:1 to 10:1, preferably 4:1 to 6:1.

In some embodiments, a source electrode and a drain electrode may be formed in the subsequent process to connect the corresponding source region and drain region, respectively. The electrode may be formed of suitable conductive materials, for example, copper, tungsten, nickel, titanium or the like. In some embodiments, metal silicide is formed in the interface of the conductive material and the source region and the drain region to increase the conductivity of the interface. In some embodiments, a multilayer interconnection structure is formed by a mosaic and/or a bi-mosaic process. In some other embodiments, tungsten plugs are formed using tungsten.

In some embodiments, in the subsequent process, contacts/vias/lines and multilayer interconnection elements (such as a metal layer and an interlayer dielectric layer) may also be formed on the substrate 102 to connect various elements or structures. For example, the multilayer interconnection includes a vertical interconnection, for example, conventional vias or contacts, and a horizontal interconnection, for example, metal lines.

The linear doped region provided herein is disposed between the gate and the drain region. Contrary to the uniform doping method, the linear doped region may make the peak electrical field of the high-voltage semiconductor surface smaller, but it may make the surface electrical field more uniform to raise the breakdown voltage of the high-voltage semiconductors and simultaneously raise the reliability of the high-voltage semiconductors. By disposing the first buried layer between the source region and the second buried layer, the resistance of the first well region may be reduced to lower on-resistance. Compared to conventional high-voltage semiconductors, the high-voltage semiconductors provided herein are more able to prevent the Kirk effect and achieve the performance of high breakdown voltage and low on resistance at the same time. In addition, by adjusting the ratio of the length of the isolation blocks to the distance between the isolation blocks (also called W_{Si}/W_{SiO2}), the length of a drift region may be reduced, and it may also be beneficial to raising the breakdown voltage of the high-voltage semiconductors.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A high-voltage semiconductor device, comprising:
a substrate having a first conductive type;
a gate disposed on the substrate;
a source region and a drain region disposed on two opposite sides of the gate respectively;
a linear doped region disposed between the gate and the drain region, and having the first conductive type, wherein the linear doped region has a nonuniform doping depth; and
a first buried layer disposed under the source region and having the first conductive type.

2. The high-voltage semiconductor device as claimed in claim 1, wherein the doping depth of the linear doped region tapers in a direction from the gate to the drain region.

3. The high-voltage semiconductor device as claimed in claim 1, wherein the linear doped region has a tapering doping concentration in a direction from the gate to the drain region.

4. The high-voltage semiconductor device as claimed in claim 1, wherein the first buried layer has a tapering doping concentration in a direction from the source region to the gate.

5. The high-voltage semiconductor device as claimed in claim 1, further comprising:
a second buried layer disposed in the substrate and under the first buried layer, wherein the second buried layer has a second conductive type opposite to the first conductive type.

6. The high-voltage semiconductor device as claimed in claim 5, wherein the second buried layer extends from under the source region to under the gate.

7. The high-voltage semiconductor device as claimed in claim 5, wherein the second buried layer does not extend under the linear doped region.

8. The high-voltage semiconductor device as claimed in claim 5, wherein a first width of the first buried layer projected on the substrate is less than a second width of the second buried layer projected on the substrate.

9. A high-voltage semiconductor device, comprising:
a gate extending in a first direction;
a source region and a drain region disposed on two opposite sides of the gate respectively and extending in the first direction;
an isolation region disposed between the gate and the drain region, wherein the isolation region has a plurality of separate isolation blocks in the first direction; and
a linear doped region disposed between the gate and the drain region, and between the plurality of isolation blocks, wherein the linear doped region has a nonuniform doping depth in a second direction perpendicular to the first direction.

10. The high-voltage semiconductor device as claimed in claim 9, wherein the linear doped region does not overlap the isolation region.

11. The high-voltage semiconductor device as claimed in claim 9, wherein the linear doped region overlaps the isolation region.

12. The high-voltage semiconductor device as claimed in claim 9, wherein the doping depth of the linear doped region tapers in a direction from the gate to the drain region.

13. The high-voltage semiconductor device as claimed in claim 9, wherein the plurality of isolation blocks have a first length along the second direction, and the linear doped region has a second length along the second direction, and a ratio of the second length to the first length is in a range from 1 to 10.

14. The high-voltage semiconductor device as claimed in claim 9, wherein the plurality of isolation blocks has a length along the second direction, and two adjacent isolation blocks have a distance along the second direction, and a ratio of the distance to the length is in a range from 1 to 10.
